(19) United States
(12) Patent Application Publication
(10) Pub. No.: US 2026/0020348 A1
(43) Pub. Date: Jan. 15, 2026

(54) DISPLAY DEVICE AND ELECTRONIC DEVICE INCLUDING THE SAME

(71) Applicant: Samsung Display Co., LTD., Yongin-si (KR)

(72) Inventors: Dong Soo KIM, Yongin-si (KR); Jae Hyeong KIM, Yongin-si (KR); Su Mi JANG, Yongin-si (KR); Won Mi HWANG, Yongin-si (KR); Bu Yong KIM, Yongin-si (KR)

(21) Appl. No.: 19/054,274

(22) Filed: Feb. 14, 2025

(30) Foreign Application Priority Data
Jul. 15, 2024 (KR) 10-2024-0093296

(51) Int. Cl. H10D 86/40

(52) U.S. Cl. CPC H10D 86/443

(57) ABSTRACT

A display device includes: a display panel including a display region, and a non-display region; and a driving element controlling driving of the display panel, and bonded to the non-display region, wherein the non-display region includes: an output pad including a first signal pad, a second signal pad, and a test pad, and bonded with the driving element; a connection part spaced apart from the output pad, and including a signal terminal electrically connected with the first signal pad and a test terminal electrically connected with the test pad; a first signal line electrically connecting the first signal pad and the signal terminal and a second signal line electrically connecting the second signal pad and the pixels; and a test line electrically connecting the test pad and the test terminal to not overlap with the first signal line and the second signal line within an element region.

### CROSS-REFERENCE TO RELATED APPLICATION

The present application claims priority to and the benefit of Korean Patent Application No. 10-2024-0093296, filed on Jul. 15, 2024, in the Korean Intellectual Property Office (KIPO), the entire disclosure of which is incorporated herein by reference.

### TECHNICAL FIELD

Aspects of some embodiments of the present disclosure relate to a display device and an electronic device including the same.

### BACKGROUND

Consumer interest in display devices is increasing with the development of multimedia. For example, consumer interest in display devices such as a liquid crystal displays (LCDs), organic light emitting displays (OLEDs), or the like is increasing. A display device may generally include a display panel and a driving element (e.g., a display driver integrated circuit (DDI)).

The above information disclosed in this Background section is only for enhancement of understanding of the background and therefore the information discussed in this Background section does not necessarily constitute prior art.

### SUMMARY

A display panel may include a display region and a non-display region. In the display region, a plurality of pixels connected to scan lines and data lines, and arranged in a matrix form or arrangement may be located. In the non-display region, an output pad part including a plurality of scan pads and data pads connected to the scan lines and data lines may be located.

The driving element is an element for controlling driving of the display panel, and may be bonded (e.g., compression bonded) to the output pad part located in the non-display region. For example, the driving element may be bonded to the output pad part through an adhesive resin (e.g., an anisotropic conductive film (ACF)). For example, an adhesive resin containing a plurality of conductive particles may be applied to the output pad part, and the driving element may be positioned on the output pad part to which the adhesive resin is applied, and then the driving element and the output pad part may be bonded by compressing. In other words, the output pad part and the driving element (e.g., a bump formed in the driving element) may be electrically connected with each other by the conductive particles contained in the adhesive resin.

There may be a bonding resistance between the output pad part and the driving element. The bonding resistance may affects the performance of the display device. For example, if the bonding resistance is increased to a reference value or higher, for example, due to an error in the manufacturing process, etc., it may decrease performance of the display device. Therefore, it may be desirable to measure the bonding resistance after manufacturing the display device to check whether a bonding defect has occurred. In order to check whether the bonding defect occurs or not, the display device may include a test pad and test lines for measuring the bonding resistance between the output pad part and the driving element.

Meanwhile, recently, as the resolution of display devices has increased and the number of signal lines has increased relatively rapidly, difficulties in routing of the test lines and signal lines may occur. For example, when the lines (e.g., test lines and/or signal lines) are not arranged (e.g., routed) efficiently (or effectively), problems in which electrostatic discharge (ESD) is introduced through the test lines and signal lines, or the lines are corroded may occur.

Aspects of some embodiments of the present disclosure include a display device and an electronic device including the same, which are robust to line corrosion and/or static electricity through efficient arrangement of lines.

According to some embodiments of the present disclosure, a display device includes: a display panel which includes a display region where a plurality of pixels are arranged, and a non-display region where the pixels are not arranged; and a driving element configured to control driving of the display panel, and bonded to the non-display region of the display panel, wherein the non-display region includes: an output pad part which includes a first signal pad, a second signal pad and a test pad, and is bonded with the driving element; a connection part which is located apart from the output pad part, and includes a signal terminal electrically connected with the first signal pad and a test terminal electrically connected with the test pad; a first signal line which electrically connects the first signal pad and the signal terminal and a second signal line which electrically connects the second signal pad and the pixels; and a test line which electrically connects the test pad and the test terminal so as not to overlap with the first signal line and the second signal line within a region (hereinafter, an element region) where the driving element is located among the non-display regions.

According to some embodiments, at least a part of the test line may be overlapped with at least a part of the first signal line and the second signal line in a non-element region.

According to some embodiments, at least a part of the first signal line and the second signal line may be formed in an inner layer of the display panel.

According to some embodiments, at least a part of the first signal line and the second signal line may be formed as a gate line.

According to some embodiments, the display panel may include a plastic or glass substrate.

According to some embodiments, the output pad part is arranged in at least five rows.

According to some embodiments, the display device may further include a connection member which is connected with the connection part at one side thereof, and is configured to connect the display device to an external device.

According to some embodiments of the present disclosure, an electronic device includes: a housing; and a display device, which corresponds to one of the above embodiments, mounted in the housing.

### BRIEF DESCRIPTION OF THE DRAWINGS

The above and other aspects, features and other characteristics of embodiments according to the present disclosure will be more clearly understood from the following detailed description taken in conjunction with the accompanying drawings, in which:

FIG. 1 is a view schematically illustrating a display device according to some embodiments of the present disclosure;

FIG. 2 is a view illustrating an example of routing of test lines and signal lines according to some embodiments of the present disclosure;

FIG. 3 is a view illustrating a display device according to some embodiments of the present disclosure; and

FIG. 4 is a view illustrating an electronic device according to some embodiments of the present disclosure.

### DETAILED DESCRIPTION

Hereinafter, aspects of some embodiments of the present disclosure will be described in more detail with reference to the accompanying drawings. Specific embodiments of the present disclosure will be illustrated in the drawings and described in the following detailed description related thereto, but it is not intended to limit the various embodiments of the present disclosure to a specific form. For example, it is obvious to those skilled in the art that the embodiments of the present disclosure may be variously modified.

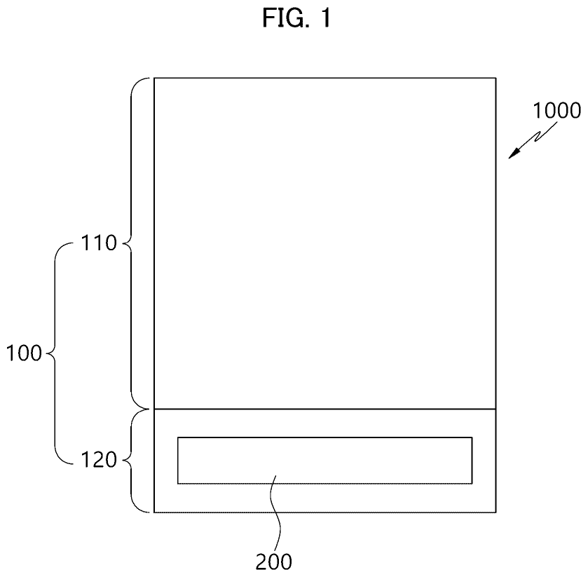

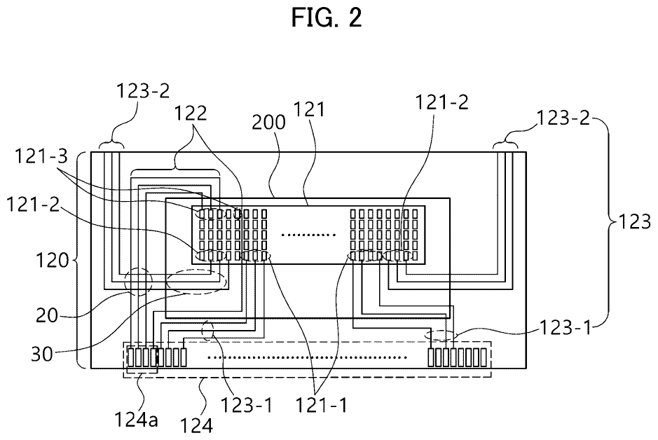

FIG. 1 is a view schematically illustrating a display device according to some embodiments of the present disclosure, and FIG. 2 is a view illustrating an example of routing of test lines and signal lines according to some embodiments of the present disclosure.

Referring to FIGS. 1 and 2, a display device 1000 according to some embodiments of the present disclosure may include a display panel 100 and a driving element 200.

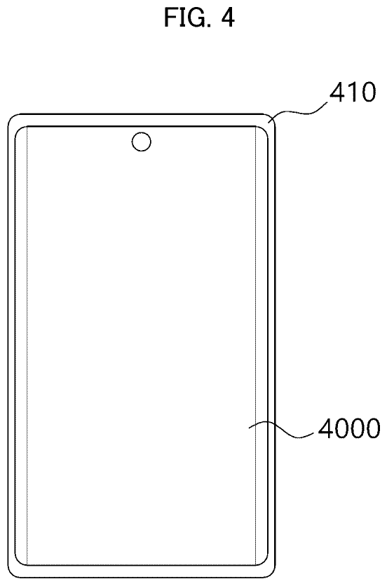

The driving element 200 may control driving of the display panel 100. For example, the driving element 200 may generate a scan signal and/or a data signal based on an input signal provided from an external device (e.g., a main printed circuit board (PCB) of an electronic device shown in FIG. 4) through a connection part 124 to control a light emission operation of the display panel 100 (e.g., pixels arranged in the display region 110).

The driving element 200 may be bonded to a non-display region 120 of the display panel 100. For example, the driving element 200 may be bonded (e.g., compression bonded) to an output pad part 121 formed in the non-display region 120 of the display panel 100. For example, an adhesive resin (e.g., an anisotropic conductive film (ACF)) containing a plurality of conductive particles is applied to the output pad part 121, and the driving element 200 is positioned on the output pad part 121 to which the adhesive resin is applied, and then the driving element 200 may be bonded to the output pad part 121 by compressing. The output pad part 121 and the driving element 200 (e.g., a bump formed in the driving element 200) may be electrically connected by the conductive particles contained in the adhesive resin.

The driving element 200 may be an integrated circuit (IC). For example, the driving element 200 may be a display driver integrated circuit (DDI).

The display panel 100 may display various images (e.g., still images or moving images) thereon. The display panel 100 may include a substrate formed of various transparent or opaque materials (such as plastic, glass, etc.). For example, the display panel 100 may include a polyimide (PI) substrate, a quartz substrate, a synthetic quartz substrate, a calcium fluoride substrate, a fluorine (F)-doped quartz substrate, a sodalime glass substrate, a non-alkali glass substrate and the like.

According to some embodiments, the display panel 100 may include a display region 110 and the non-display region 120.

A plurality of pixels may be arranged in the display region 110. The light emission operation of the plurality of pixels may be controlled by the driving element 200. The display region 110 may include a sealing structure (e.g., a thin film or an encapsulation substrate) to prevent or reduce instances of contaminants such as moisture, oxygen, etc. penetrating into the pixels.

The non-display region 120 is a region (e.g., outside a footprint of the display region 110) where the pixels are not present or arranged, and the driving element 200 may be bonded thereto. The non-display region 120 may include the output pad part 121, a test line 122, a signal line 123, and the connection part 124.

The output pad part 121 may include a plurality of output pads. The plurality of output pads may include a signal pad (e.g., a first signal pad 121-1 and a second signal pad 121-2) and a test pad 121-3. The test pad 121-3 may be electrically connected to a test terminal 124a of the connection part 124 through the test line 122. The signal pad may include a first signal pad 121-1 and a second signal pad 121-2. The first signal pad 121-1 may be electrically connected to a signal terminal of the connection part 124 through a part of the signal line 123 (hereinafter, a first signal line 123-1). The second signal pad 121-2 may be electrically connected to a plurality of pixels through another part of the signal line 123 (hereinafter, a second signal line 123-2).

The plurality of output pads may include metal, an alloy, a metal nitride, a conductive metal oxide, a transparent conductive material and the like. In addition, the plurality of output pads may be formed by a combination of a plurality of materials. Further, the plurality of output pads may have a multilayer structure including a plurality of metal layers.

The plurality of output pads may be arranged in multiple rows and multiple columns. According to an embodiment, as the number of lines is increased rapidly due to an increase in the resolution of the display device 1000, the plurality of output pads may be arranged in at least five rows. Meanwhile, the arrangement form of the output pads and the positions of the test pads 121-3 and the signal pads 121-1 and 121-2 illustrated in FIG. 2 are only an example, and do not limit the present disclosure thereto.

The test line 122 may be used to measure a bonding resistance between the driving element 200 and the output pad part 121. The test line 122 may electrically connect the test pad 121-3 of the output pad part 121 and the test terminal 124a of the connection part 124. According to an embodiment, the test line 122 is not overlapped with the signal line 123 within a region (hereinafter, an element region) where the driving element 200 is located among the non-display regions 120. Meanwhile, at least a part of the test line 122 may be overlapped with at least a part of the signal line 123 outside the element region (hereinafter, a non-element region). Here, the overlapping does not mean that the test line 122 and the signal line 123 are physically in contact (connected), but means that the test line 122 and the signal line 123 are spaced apart from each other in a vertical direction, but when viewed the display device 1000 in the vertical direction from above the display device 1000, the test line 122 and the signal line 123 appear to be overlapped with each other. Meanwhile, the non-display region 120 has an insulation film (e.g., an organic insulation film) formed on a surface thereof. However, since the output pad part 121 should be exposed to an outside, the insulation film is removed from the element region.

The signal line 123 may electrically connect the driving element 200 and the connection part 124. In addition, the signal line 123 may electrically connect pixels of the display region 110 and the driving element 200. For example, the signal line 123 may include the first signal line 123-1 which connects the first signal pad 121-1 of the output pad part 121 and the signal terminals of the connection part 124, respectively, and the second signal line 123-2 (e.g., scan lines and data lines) which connects the second signal pad 121-2 of the output pad part 121 and a plurality of pixels located in the display region 110, respectively.

According to an embodiment, the signal line 123 is not overlapped with the test line 122 within the element region. In addition, at least a part of the signal line 123 may be overlapped with at least a part of the test line 122 in the non-element region. Meanwhile, at least a part of the signal line 123 (e.g., a part of a line 30 passing through the element region) may be formed in an inner layer of the display panel 100 so as not to be exposed to the outside. For example, at least a part of the signal line 123 may be formed as a gate line.

The connection part 124 may be located apart from the output pad part 121. For example, the connection part 124 may be located at a lower portion of the non-display region 120. The connection part 124 may be connected with a connection member (e.g., a flexible printed circuit board (FPCB)) which connects the display device 1000 to an external device (e.g., the main PCB).

The connection part 124 may include a test terminal 124a electrically connected with the test pad 121-3 of the output pad part 121 and a signal terminal electrically connected with the first signal pad 121-1. In addition, the connection part 124 may include a driving voltage terminal for providing a driving voltage from an external device to the display panel 100. The test terminal 124a may come into contact with a probe pin of a test device during a process of testing a bonding defect between the output pad part 121 and the driving element 200. In this case, the test device may measure a bonding resistance or voltage through the probe pin to determine whether a bonding defect occurs or not.

In alternative display devices, the test line 122 and the signal line 123 may be overlapped in the element region from which the insulation film is removed. In addition, the test line 122 may be formed as a source line which is exposed to the outside. In this case, static electricity may be introduced into the test line through a gap formed between the driving element and the display panel. At this time, the static electricity introduced into the test line may also be introduced into the overlapped signal lines. As such, the alternative display devices may have a problem of being vulnerable to the static electricity. In contrast, in the display device 1000 according to some embodiments of the present disclosure, because the test line 122 and the signal line 123 are not overlapped in the element region, but overlapped in the non-element region, it may be robust to the static electricity (ESD) (e.g., prevent or reduce damage due to the static electricity). This is because the static electricity is blocked by the insulation film (e.g., an organic insulation film) formed on the surface of the non-element region.

Further, in the alternative display devices, a line (e.g., the signal line 123) passing through the element region is formed as a source line which is exposed to the outside. Thereby, the alternative display devices have a problem in which the lines are corroded. In contrast, in the display device 1000 according to some embodiments of the present disclosure, the line (e.g., the signal line 123) passing through the element region is formed as a gate line which is not exposed to the outside. As such, according to some embodiments of the present disclosure, it may be possible to prevent or reduce corrosion of the line by preventing or reducing exposure of the line (e.g., the signal line 123) to the outside.

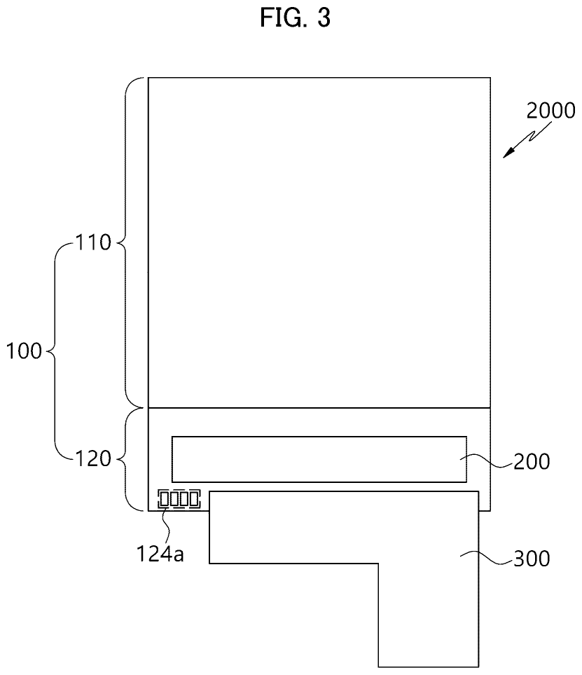

FIG. 3 is a view illustrating a display device according to some embodiments of the present disclosure.

Referring to FIG. 3, a display device 2000 according to some embodiments of the present disclosure may include a display panel 100, a driving element 200, and a connection member 300. In other words, the display device 2000 may further include the connection member 300 compared to the display device 1000 shown in FIGS. 1 and 2. Therefore, the display panel 100 and the driving element 200 shown in FIG. 3 some repetitive description of the same or similar components may be omitted for brevity.

The connection member 300 may connect the display device 2000 and an external device (e.g., the main printed circuit board (PCB) of the electronic device). The connection member 300 may have one end connected to the connection part 124 of the display device 2000 and the other end connected to the external device. In some embodiments, the connection member 300 may not be connected with the test terminal 124a of the connection part 124. This is because the probe pin of the test device should be in contact with the test terminal 124a.

The connection member 300 may be formed as a flexible printed circuit board (FPCB). The connection member 300 may be formed integrally with the display device 2000. Alternatively, the connection member 300 may be formed as a separate configuration from the display device 2000.

FIG. 4 is a view illustrating an electronic device according to some embodiments of the present disclosure.

Referring to FIG. 4, the electronic device according to some embodiments of the present disclosure may include a display device 4000.

The display device 4000 may be mounted inside the electronic device. For example, the display device 4000 may be mounted in a housing 410 of the electronic device so that the display region is exposed through a front surface of the electronic device. The display device 4000 may be the display device 1000 shown in FIGS. 1 and 2 or the display device 2000 shown in FIG. 3. Therefore, the display device 4000 will not be described in detail. As described in FIGS. 1 to 3, the display device 4000 included in the electronic device is robust to the static electricity and/or line corrosion. Accordingly, the electronic device including the display device 4000 may also be robust to the static electricity and/or line corrosion. Thereby, various embodiments of the present disclosure may enhance (or improve) the reliability of the electronic device.

Due to efficient arrangement of the lines (e.g., the test line 122 and/or signal line 123), various embodiments of the present disclosure may prevent (or reduce or minimize) damage (or breakage) to the display device caused by the electrostatic discharge (ESD). For example, by arranging (e.g., routing) the test line 122 and signal line 123 so as not to be overlapped in a lower region of the driving element, the present disclosure may prevent (or reduce or minimize) the damage (or breakage) to the display device caused by the electrostatic discharge (ESD). In addition, various embodiments of the present disclosure may reduce (or minimize) corrosion damage to the lines by minimizing external exposure of the lines (e.g., the test line 122 and/or signal line 123). For example, the present disclosure may prevent or reduce corrosion of the line by forming the line as a gate line which is not exposed to the outside. The effects according to various embodiments of the present disclosure are not limited to the contents described above, and more diverse effects may be understood by those skilled in the art from the description stated in the present disclosure.

The electronic device according to various embodiments of the present disclosure may be various types of devices. The electronic device may include, for example, a portable communication device (e.g., a smart phone), a computer device, a portable multimedia device, a portable medical device, a camera, a multimedia device installed in, embedded in, or integrally formed with an automobile, or a home appliance device. The electronic device according to embodiments of the present disclosure is not limited to the above-described devices.

Various embodiments of the present disclosure and the terms used herein do not limit the technical characteristics described in the present disclosure to specific embodiments, and should be construed to include various modifications, equivalents, or replacements of the embodiments. With regard to the description of the drawings, similar or related components may be denoted by similar reference numerals. It is to be understood that a singular form of a noun corresponding to an item may include one or a plurality of the things, unless the relevant context clearly indicates otherwise. As used herein, each of phrases such as “A or B,” “at least one of A and B,” “at least one of A or B,” “A, B or C,” “at least one of A, B and C,” and “at least one of A, B or C” may include any one, or all possible combinations of these items enumerated together in the corresponding one of the phrases. As used herein, the terms such as “1st” and “2nd,” or “first” and “second” may be used to simply distinguish the corresponding component from another component, and does not limit the corresponding components in other aspects (e.g., an importance or order). It is to be understood that if a component (e.g., a first component) is referred to as “coupled to” or “connected to” another component (e.g., a second component), with or without the term “operatively” or “communicatively,” it means that the component may be coupled to the other component directly (e.g., by wire), wirelessly, or via a third component.

The term “module” used in various embodiments of the present disclosure may include a unit implemented in hardware, software or firmware way, and for example, may be used interchangeably with the terms such as logic, a logic block, a part, or a circuit. The module may be a part integrally formed therewith, or a minimum unit of the part or a portion thereof which performs one or more functions. For example, according to some embodiments, the module may be implemented in a form of an application-specific integrated circuit (ASIC).

According to various embodiments, each component or element (e.g., a module or program) of the above-described components or elements may include one or a plurality of entities, and some of the plurality of entities may be disposed to other components with being separated therefrom. According to various embodiments, among the above-described components, one or more components or operations thereof may be omitted or one or more other components or operations thereof may be added to the components. Alternatively or additionally, the plurality of components (e.g., the modules or programs) may be integrated into one component. In this case, the integrated components may perform one or more functions of each component of the plurality of components in a way that they are the same as or similar to the functions performed by the corresponding components among the plurality of components before the integration. According to various embodiments, operations performed by the modules, programs, or other components may be executed sequentially, in parallel, repeatedly, or heuristically, one or more operations may be executed in another sequence or omitted, or one or more other operations may be added thereto.

What is claimed is:

1. A display device comprising:
a display panel including a display region where a plurality of pixels are arranged, and a non-display region where the pixels are not arranged; and
a driving element configured to control driving of the display panel, and bonded to the non-display region of the display panel,
wherein the non-display region comprises:
an output pad part including a first signal pad, a second signal pad, and a test pad, and bonded with the driving element;
a connection part spaced apart from the output pad part, and including a signal terminal electrically connected with the first signal pad and a test terminal electrically connected with the test pad;
a first signal line electrically connecting the first signal pad and the signal terminal and a second signal line electrically connecting the second signal pad and the pixels; and
a test line electrically connecting the test pad and the test terminal so as not to overlap with the first signal line and the second signal line within an element region where the driving element is in the non-display region.

2. The display device according to claim 1, wherein at least a part of the test line overlaps at least a part of the first signal line and the second signal line in a non-element region.

3. The display device according to claim 2, wherein at least a part of the first signal line and the second signal line are formed in an inner layer of the display panel.

4. The display device according to claim 3, wherein at least a part of the first signal line and the second signal line are formed as a gate line.

5. The display device according to claim 1, wherein the display panel comprises a plastic or glass substrate.

6. The display device according to claim 1, wherein the output pad part is arranged in at least five rows.

7. The display device according to claim 1, further comprising a connection member connected with the connection part at one side thereof, and is configured to connect the display device to an external device.

8. An electronic device comprising:
a housing; and
a display device mounted in the housing,
wherein the display device comprises:
a display panel including a display region where a plurality of pixels are arranged, and a non-display region where the pixels are not arranged; and
a driving element configured to control driving of the display panel, and bonded to the non-display region of the display panel,
wherein the non-display region comprises:
an output pad part including a first signal pad, a second signal pad, and a test pad, and bonded with the driving element;
a connection part spaced apart from the output pad part, and includes a signal terminal electrically connected with the first signal pad and a test terminal electrically connected with the test pad;
a first signal line electrically connecting the first signal pad and the signal terminal and a second signal line electrically connecting the second signal pad and the pixels; and
a test line electrically connecting the test pad and the test terminal so as not to overlap with the first signal line and the second signal line within an element region where the driving element is in the non-display region.

9. The electronic device according to claim 8, wherein at least a part of the test line is overlapped with at least a part of the first signal line and the second signal line in a non-element region.

10. The electronic device according to claim 9, wherein at least a part of the first signal line and the second signal line are formed in an inner layer of the display panel.

11. The electronic device according to claim 10, wherein at least a part of the first signal line and the second signal line are formed as a gate line.

12. The electronic device according to claim 8, wherein the display panel comprises a plastic or glass substrate.

13. The electronic device according to claim 8, wherein the output pad part is arranged in at least five rows.

14. The electronic device according to claim 8, further comprising a connection member connected with the connection part at one side thereof, and is configured to connect the display device to an external device.
